(19) United States
(12) Patent Application Publication
(10) Pub. No.: US 2021/0327956 A1
(43) Pub. Date: Oct. 21, 2021

(54) DISPLAY PANEL, MAUFACTURING METHOD THEREOF, AND ELECTRONIC DEVICE

(71) Applicant: SHENZHEN ROYOLE TECHNOLOGIES CO., LTD., Shenzhen (CN)

(72) Inventors: Yu-Min WANG, Shenzhen (CN); Ze YUAN, Shenzhen (CN); Jiahao KANG, Shenzhen (CN)

(21) Appl. No.: 17/227,189

(22) Filed: Apr. 9, 2021

(30) Foreign Application Priority Data
Apr. 15, 2020 (CN) 202010293479.8

(51) Int. Cl. H01L 27/15; H01L 27/32; H01L 51/00; H01L 51/52; H01L 51/56

(52) U.S. Cl. CPC H01L 27/156; H01L 27/3244; H01L 2227/323; H01L 51/5253; H01L 51/56; H01L 51/0097

(57) ABSTRACT

A display panel is provided. The display panel includes multiple first flexible sub-layers, multiple light-emitting circuits, multiple light-emitting elements, multiple second flexible sub-layers, and an elastic member. For each second flexible sub-layer, the second flexible sub-layer is in contact with a surface of a corresponding light-emitting circuit away from a corresponding first flexible sub-layer, at least partially covers the corresponding light-emitting circuit, and is provided with a rough structure on a surface away from the corresponding first flexible sub-layer. The elastic member is arranged on sides of the multiple second flexible sub-layers away from the multiple first flexible sub-layers, and covers the above components. A manufacturing method of a display panel and an electronic device is further provided.

### CROSS-REFERENCE TO RELATED APPLICATION(S)

This application claims priority to Chinese Application Patent Serial No. 202010293479.8, filed on Apr. 15, 2020, the entire disclosure of which is hereby incorporated by reference.

### TECHNICAL FIELD

This disclosure relates to the technical field of display, and more particularly to a display panel, a manufacturing method thereof, and an electronic device.

### BACKGROUND

With the development of science and technology, various display devices are widely used in people's life and work, for example, televisions, computers, mobile phones, personal digital assistants (PADs), or display devices used for airplanes, vehicles, voyage, railway transportation, or robots. For bendable and foldable display devices, manufacturing of flexible screens especially yield of the flexible screens is a main technical problem. The existing manufacturing method of a flexible screen is as follows. A display element is formed on a rigid substrate, an elastic substrate is formed on the display element, and then the display element and the elastic substrate are peeled from the rigid substrate. Since adhesion between the elastic substrate and the display element is relatively low, during peeling, the elastic substrate may also be separated from the display element, thereby reducing the yield of the flexible screens. In addition, since the adhesion between the elastic substrate and the display element is relatively low, during stretching of the flexible screen, the elastic substrate may also be separated from the display element, which may damage the flexible screen.

### SUMMARY

The disclosure aims to solve at least one of technical problems existed in the related art. According to a first aspect of the disclosure, a display panel is provided. The display panel includes multiple first flexible sub-layers, multiple light-emitting circuits, multiple light-emitting elements, multiple second flexible sub-layers, and an elastic member.

The multiple first flexible sub-layers are spaced apart from each other, and each two adjacent first flexible sub-layers cooperatively define a spacing region.

Each light-emitting circuit is arranged on a side of a corresponding first flexible sub-layer.

For each light-emitting element, the light-emitting element is arranged on a side of a corresponding light-emitting circuit away from a corresponding first flexible sub-layer, and is coupled to the corresponding light-emitting circuit, and different light-emitting elements are electrically coupled to different light-emitting circuits.

For each second flexible sub-layer, the second flexible sub-layer is in contact with a surface of a corresponding light-emitting circuit away from a corresponding first flexible sub-layer, at least partially covers the corresponding light-emitting circuit, and is provided with a rough structure on a surface away from the corresponding first flexible sub-layer.

The elastic member is arranged on sides of the multiple second flexible sub-layers away from the multiple first flexible sub-layers, and covers the multiple second flexible sub-layers, the multiple light-emitting elements, the multiple light-emitting circuits, and the multiple first flexible sub-layers, and is filled in each spacing region between each two adjacent first flexible sub-layers.

In at least one implementation, each light-emitting circuit comprises a driving circuit consisted of thin film transistors, where the light-emitting circuits on each two adjacent first flexible sub-layers are coupled via a connection line to form a driving circuit array.

In at least one implementation, the first flexible sub-layer and the second flexible sub-layer each comprise an organic layer, a metal sheet, or an ultra-thin glass.

In at least one implementation, for each second flexible sub-layer, the second flexible sub-layer is in contact with a surface of a corresponding light-emitting element away from a corresponding first flexible sub-layer, and covers a corresponding light-emitting circuit and the corresponding light-emitting element.

In at least one implementation, for each light-emitting element, the light-emitting element is arranged on a surface of a corresponding second flexible sub-layer away from a corresponding first flexible sub-layer, and has an orthographic projection on the corresponding first flexible sub-layer that at most partially overlaps with an orthographic projection of the corresponding second flexible sub-layer on the corresponding first flexible sub-layer.

In at least one implementation, each second flexible sub-layer defines a through hole, where the through hole defined in each second flexible sub-layer extends to a surface of a corresponding light-emitting circuit away from a corresponding first flexible sub-layer, and receives a connection piece for connecting a corresponding light-emitting element to the corresponding light-emitting circuit.

In at least one implementation, the elastic member in a molten state and a surface of the second flexible sub-layer in contact with the elastic member cooperatively define a contact angle smaller than 90 degrees.

In at least one implementation, the rough structure is a microstructure, where the microstructure has a cylindrical shape, a tapered shape, or an irregular shape.

In at least one implementation, the light-emitting element is an inorganic light-emitting diode or an organic light-emitting diode.

In at least one implementation, the first flexible sub-layer and the second flexible sub-layer are both made from polyimide or acrylic acid.

According to a second aspect of the disclosure, a manufacturing method of a display panel is provided. The manufacturing method includes the following.

A substrate is provided.

A first flexible layer is formed on the substrate.

Multiple light-emitting circuits are formed on a surface of the first flexible layer away from the substrate, where the multiple light-emitting circuits are spaced apart from each other, and each two adjacent light-emitting circuits cooperatively define a gap region.

A corresponding light-emitting element and a corresponding second flexible sub-layer are formed on a side of each light-emitting circuit away from the first flexible layer to form multiple light-emitting elements and multiple second flexible sub-layers, a part of the first flexible layer corresponding to at least a part of each gap region between each two adjacent light-emitting circuits are removed to form multiple first flexible sub-layers and a spacing region each defined between each two adjacent first flexible sub-layers, and a rough structure is formed on a surface of each second flexible sub-layer away from a corresponding light-emitting circuit.

An elastic member is formed on sides of the multiple second flexible sub-layers away from the multiple first flexible sub-layers, where the elastic member covers the multiple second flexible sub-layers, the multiple light-emitting elements, the multiple light-emitting circuits, and the multiple first flexible sub-layers and is filled in each spacing region between each two adjacent first flexible sub-layers.

The substrate is removed.

In at least one implementation, “forming, on the side of each light-emitting circuit away from the first flexible layer, the corresponding light-emitting element and the corresponding second flexible sub-layer to form the multiple light-emitting elements and the multiple second flexible sub-layers, removing the part of the first flexible layer corresponding to at least the part of each gap region between each two adjacent light-emitting circuits to form the multiple first flexible sub-layers and the spacing regions each defined between each two adjacent first flexible sub-layers, and forming the rough structure on the surface of each second flexible sub-layer away from the corresponding light-emitting circuit” includes the following. A corresponding light-emitting element is formed on a surface of each light-emitting circuit away from the first flexible layer to form the multiple light-emitting elements. A second flexible layer is formed on sides of the multiple light-emitting elements away from the first flexible layer, where the second flexible layer covers the multiple light-emitting circuits and the multiple light-emitting elements. The part of the first flexible layer and a part of the second flexible layer that correspond to at least the part of each gap region between each two adjacent light-emitting circuits are removed to form the multiple first flexible sub-layers, the spacing regions each defined between each two adjacent first flexible sub-layers, and the multiple second flexible sub-layers, where each second flexible sub-layer covers a corresponding light-emitting element and a corresponding light-emitting circuit. The rough structure is formed on the surface of each second flexible sub-layer away from the corresponding light-emitting circuit.

In at least one implementation, “forming, on the side of each light-emitting circuit away from the first flexible layer, the corresponding light-emitting element and the corresponding second flexible sub-layer to form the multiple light-emitting elements and the multiple second flexible sub-layers, removing the part of the first flexible layer corresponding to at least the part of each gap region between each two adjacent light-emitting circuits to form the multiple first flexible sub-layers and the spacing regions each defined between each two adjacent first flexible sub-layers, and forming the rough structure on the surface of each second flexible sub-layer away from the corresponding light-emitting circuit” includes the following. A second flexible layer is formed on sides of the multiple light-emitting circuits away from the first flexible layer, where the second flexible layer covers the multiple light-emitting circuits. The part of the first flexible layer and a part of the second flexible layer that correspond to at least the part of each gap region between each two adjacent light-emitting circuits are removed to form the multiple first flexible sub-layers, the spacing regions each defined between each two adjacent first flexible sub-layers, and the multiple second flexible sub-layers, and forming the rough structure on the surface of each second flexible sub-layer away from the corresponding light-emitting circuit. A corresponding light-emitting element is formed on a surface of each second flexible sub-layer away from a corresponding first flexible sub-layer to form the multiple light-emitting elements, where each light-emitting element partially connects to a surface of a corresponding second flexible sub-layer away from a corresponding first flexible sub-layer, and has an orthographic projection on the corresponding first flexible sub-layer that at most partially overlaps with an orthographic projection of the corresponding second flexible sub-layer on the corresponding first flexible sub-layer.

In at least one implementation, “forming, on the surface of each second flexible sub-layer away from the corresponding first flexible sub-layer, the corresponding light-emitting element to form the multiple light-emitting elements, where each light-emitting element partially connects to the surface of the corresponding second flexible sub-layer away from the corresponding first flexible sub-layer are partially coupled, and has the orthographic projection on the corresponding first flexible sub-layer that at most partially overlaps with the orthographic projection of the corresponding second flexible sub-layer on the corresponding first flexible sub-layer” includes the following. A through hole is defined in each second flexible sub-layer, where the through hole defined in each second flexible sub-layer extends to a surface of a corresponding light-emitting circuit away from a corresponding first flexible sub-layer, and a connection piece is formed in each through hole. A corresponding light-emitting element is formed on a surface of each connection piece away from a corresponding first flexible sub-layer to form the multiple light-emitting elements, where each light-emitting element partially connects to the surface of the corresponding second flexible sub-layer away from the corresponding first flexible sub-layer, and has the orthographic projection on the corresponding first flexible sub-layer that at most partially overlaps with the orthographic projection of the corresponding second flexible sub-layer on the corresponding first flexible sub-layer.

In at least one implementation, the elastic member is formed on the sides of the multiple second flexible sub-layers away from the multiple first flexible sub-layers as follows. A molten elastic member material is formed on the sides of the multiple second flexible sub-layers away from the multiple first flexible sub-layers in such a manner that the elastic member material is filled in each spacing region between each two adjacent first flexible sub-layers, where the molten elastic member material and a surface of each second flexible sub-layer away from a corresponding first flexible sub-layer cooperatively define a contact angle smaller than 90 degrees. The molten elastic member material is cured to form the elastic member, where the elastic member covers the multiple second flexible sub-layers, the multiple light-emitting elements, the multiple light-emitting circuits, and the multiple first flexible sub-layers and is filled in each spacing region between each two adjacent first flexible sub-layers.

In at least one implementation, the rough structure is a microstructure, where the microstructure has a cylindrical shape, a tapered shape, or an irregular shape.

In at least one implementation, the rough structure is formed on the surface of each second flexible sub-layer away from the corresponding light-emitting circuit as follows. Plasma etching is performed on the surface of each second flexible sub-layer away from the corresponding light-emitting circuit to form the rough structure.

According to a third aspect of the disclosure, an electronic device is provided. The electronic device includes the display panel described in any implementation of the disclosure.

Implementing the technical solutions of the disclosure may have the following advantageous effects. According to the display panel provided herein, since each second flexible sub-layer is provided with the rough structure on the surface away from the first flexible sub-layer, the adhesion between the elastic member and the second flexible sub-layer is improved, which can prevent the elastic member in the display panel from being separated from components inside the elastic member.

### BRIEF DESCRIPTION OF THE DRAWINGS

In order to describe technical solutions of implementations of the disclosure more clearly, the following will give a brief description of accompanying drawings used for describing the implementations of the disclosure. Apparently, the accompanying drawings described below merely illustrate some implementations of the disclosure. Those of ordinary skill in the art can also obtain other accompanying drawings based on the accompanying drawings described below without creative efforts.

FIG. 1 is a schematic structural view illustrating a display panel according to implementations of the disclosure.

FIG. 2 is a schematic structural view illustrating a second flexible sub-layer having a microstructure thereon according to implementations of the disclosure.

FIG. 3 is a schematic structural view illustrating a display panel according to other implementations of the disclosure.

FIG. 4 is a flow chart illustrating a manufacturing method of a display panel according to implementations of the disclosure.

FIG. 5 is a structural view of a manufacturing process of the display panel according to implementations of the disclosure.

FIG. 6 is a sub-flow chart illustrating operation at S400 in FIG. 4.

FIG. 7 is a sub-flow chart illustrating operation at S500 in FIG. 4.

FIG. 8 is a flow chart illustrating part of operations of a manufacturing method of a display panel according to other implementations of the disclosure.

FIG. 9 is a structural view illustrating a manufacturing process of the display panel according to other implementations of the disclosure.

FIG. 10 is a sub-flow chart illustrating operation at S430-II in FIG. 8.

FIG. 11 is a schematic structural diagram illustrating an electronic device according to implementations of the disclosure.

### DETAILED DESCRIPTION

The following are some implementations of the disclosure. It should be noted that for those of ordinary skill in the art, various improvements and modifications can be made without departing from the principle of the disclosure, and these improvements and modifications also fall within the protection scope of the disclosure.

The terms “first”, “second”, and the like used in the specification, the claims, and the accompany drawings of the disclosure are used to distinguish different objects rather than describe a particular order. The terms “include”, “comprise”, and “have” as well as variations thereof are intended to cover non-exclusive inclusion. For example, a process, method, system, product, or apparatus including a series of steps or units is not limited to the listed steps or units, on the contrary, it can optionally include other steps or units that are not listed; alternatively, other steps or units inherent to the process, method, product, or apparatus can be included either.

The term “implementation” referred to herein means that a particular feature, structure, or characteristic described in conjunction with the implementations may be contained in at least one implementation of the disclosure. The phrase appearing in various places in the specification does not necessarily refer to the same implementation, nor does it refer to an independent or alternative implementation that is mutually exclusive with other implementations. It is expressly and implicitly understood by those skilled in the art that an implementation described herein may be combined with other implementations.

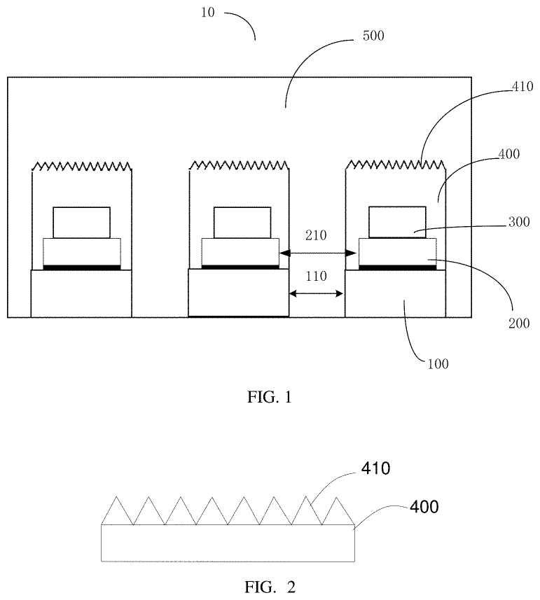

As illustrated in FIG. 1, a display panel 10 is provided in an implementation of the disclosure. The display panel 10 includes multiple first flexible sub-layers 100, multiple light-emitting circuits 200, multiple light-emitting elements 300, multiple second flexible sub-layers 400, and an elastic member 500. The multiple first flexible sub-layers 100 are spaced apart from each other. Each two adjacent first flexible sub-layers 100 cooperatively define a spacing region 110 therebetween. The multiple light-emitting circuits 200 are respectively arranged on the multiple first flexible sub-layers 100. In one example, each light-emitting circuit 200 is arranged on a surface of a corresponding first flexible sub-layer 100. For each light-emitting element 300, the light-emitting element 300 is arranged on a side of a corresponding light-emitting circuit 200 away from a corresponding first flexible sub-layers 100, is coupled to the corresponding light-emitting circuit 200. Different light-emitting elements 300 are electrically coupled to different light-emitting circuits 200. The light-emitting circuit 200 is configured to drive the light-emitting element 300 to emit light. In the implementation, the light-emitting element 300 is an inorganic light emitting diode or an organic light emitting diode.

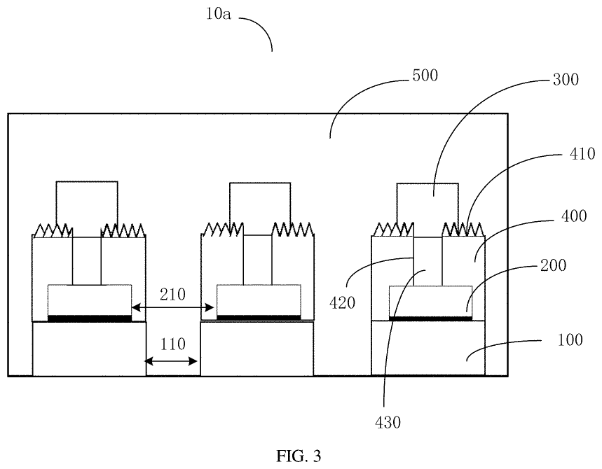

For each second flexible sub-layer 400, the second flexible sub-layer 400 is arranged on a side of a corresponding light-emitting circuit 200 away from a corresponding first flexible sub-layer 100, at least partially covers the light-emitting circuit 200, and is provided with a rough structure 410 on a surface away from the corresponding first flexible sub-layer 100. In the implementation, the light-emitting element 300 is disposed on a surface of the light-emitting circuit 200 away from the first flexible sub-layer 100, and the second flexible sub-layer 400 is in contact with a surface of the light-emitting element 300 away from the light-emitting circuit 200 and covers the light-emitting circuit 200 and the light-emitting element 300. In other words, the first flexible sub-layer 100 and the second flexible sub-layer 400 wrap the light-emitting circuit 200 and the light-emitting element 300 to prevent the light-emitting circuit 200 and the light-emitting element 300 from being corroded by water vapor or oxygen. In other implementations, as illustrated in FIG. 3, the second flexible sub-layer 400 is arranged on a side of the light-emitting circuit 200 away from the first flexible sub-layer 100 without covering the light-emitting element 300, and the light-emitting element 300 is disposed on a surface of the second flexible sub-layer 400 away from the first flexible sub-layer 100. In other implementations, each second flexible sub-layer 400 may be provided with the rough structures 410 on two side surfaces to further improve adhesion between the second flexible sub-layer 400 and the elastic member 500.

The elastic member 500 is arranged on sides of the multiple second flexible sub-layers 400 away from the multiple first flexible sub-layers 100. The elastic member 500 covers the multiple second flexible sub-layers 400, the multiple light-emitting elements 300, the multiple light-emitting circuits 200, and the multiple first flexible sub-layers 100, and is filled in the spacing regions 110. Since each second flexible sub-layer 400 is provided with the rough structure 410 on the surface away from the first flexible sub-layer 100, in a condition that the rough structure 410 is connected to the elastic member 500, a surface of the elastic member 500 connected to the rough structure 410 is relatively rough, which can improve the adhesion between the elastic member 500 and the second flexible sub-layers 400.

In the display panel 10 of the disclosure, each second flexible sub-layer 400 is provided with the rough structure 410 on the surface away from the first flexible sub-layer 100, and thus the adhesion between the elastic member 500 and the second flexible sub-layers 400 is improved, thereby preventing the elastic member 500 from being separated from components (such as the second flexible sub-layers 400, the light-emitting elements 300, the light-emitting circuits 200, and the first flexible sub-layers 100) inside the elastic member 500 during stretching of the display panel 10. In addition, when the display panel 10 is prepared on a substrate, during peeling the substrate from the display panel 10, the adhesion between the elastic member 500 and the second flexible sub-layers 400 can prevent the components (including the second flexible sub-layers 400, the light-emitting elements 300, the light-emitting circuits 200, and the first flexible sub-layers 100) inside the elastic member 500 from being separated from the elastic member 500, thereby reducing damage of the display panel 10 and increasing the yield of the display panels 10.

Furthermore, since the light-emitting elements 300 in the display panel 10 of the disclosure are islanded with the multiple first flexible sub-layers 100, when the elastic member 500 is filled between the multiple first flexible sub-layers 100, the flexibility of the display panel 10 can be further improved.

In at least one implementation, the light-emitting circuit 200 includes a driving circuit consisted of thin film transistors, and the light-emitting circuits 200 on each two adjacent first flexible sub-layers 100 are coupled via a connection line (not illustrated) to form a driving circuit array. The connection line may be arranged in the spacing regions 110 to achieve electrical coupling between the light-emitting circuits 200. The light-emitting circuit 200 can further include a power line, a data line, a scan line, or the like.

In at least one implementation, the first flexible sub-layer 100 and the second flexible sub-layer 400 each include an organic layer, a metal sheet, or an ultra-thin glass. In the implementation, the organic layer is adopted since the organic layer has a relatively good stretchability. For example, the first flexible sub-layer 100 and the second flexible sub-layer 400 are both made from polyimide or acrylic. Furthermore, a transparent organic layer is adopted. For example, the second flexible sub-layer 400 is made from transparent polyimide or acrylic. The transparent organic layer can increase a light-emitting rate of the light-emitting element 300, thereby improving the display effect.

In at least one implementation, a contact angle between the elastic member 500 in a molten state and a surface of the second flexible sub-layer 400 in contact with the elastic member 500 is smaller than 90 degrees. For solid-liquid contact with the contact angle of smaller than 90 degrees, the rough surface facilitates surface wetting, thereby improving the adhesion between the elastic member 500 and the second flexible sub-layer 400. The materials of the elastic member 500 and the second flexible sub-layer 400 in the implementation of the disclosure are determined according to the contact angle (the contact angle smaller than 90 degrees is good) between the elastic member 500 in the molten state and the surface of the second flexible sub-layer 400 in contact with the elastic member 500.

As illustrated in FIG. 2, in at least one implementation, the rough structure 410 is a microstructure. The microstructure may have a cylindrical shape, a tapered shape, or an irregular shape.

As illustrated in FIG. 3, a display panel 10a is provided in an implementation of the disclosure. The display panel 10a differs from the display panel 10 in that: in the display panel 10a, for each light-emitting element 300, the light-emitting element 300 is arranged on a surface of a corresponding second flexible sub-layer 400 away from a corresponding first flexible sub-layer 100, and has an orthographic projection on the corresponding first flexible sub-layer 100 that at most partially overlaps with an orthographic projection of the corresponding second flexible sub-layer 400 on the corresponding first flexible sub-layer 100. That is, the orthographic projection of the light-emitting element 300 on the first flexible sub-layer 100 may partially overlap or may not overlap with the orthographic projection of the corresponding second flexible sub-layer 400 on the corresponding first flexible sub-layer 100. In the display panel 10a, the second flexible sub-layer 400 is arranged on a side of the light-emitting circuit 200 away from the first flexible sub-layer 100 without covering the light-emitting element 300, and the light-emitting element 300 is disposed on a surface of the second flexible sub-layer 400 away from the first flexible sub-layer 100. In one example, the orthographic projection of the second flexible sub-layer 400 on the first flexible sub-layer 100 and the orthographic projection of the light-emitting element 300 on the first flexible sub-layer 100 at most partially overlap. In other words, a surface of a part of the second flexible sub-layer 400 that is not provided with the light-emitting element 300 and away from the first flexible sub-layer 100 is provided with the rough structure 410, and the rough structure 410 is in contact with the elastic member 500, which can improve the adhesion between the second flexible sub-layer 400 and the elastic member 500. In other implementations, a surface of a part of the second flexible sub-layer 400 that is in contact with the light-emitting element 300 and away from the first flexible sub-layer 100 can also be provided with the rough structure 410, which can improve the adhesion between the second flexible sub-layer 400 and the light-emitting element 300.

In at least one implementation, each second flexible sub-layer 400 defines a through hole 420. The through hole 420 defined in each second flexible sub-layer 400 extends to a surface of a corresponding light-emitting circuit 200 away from a corresponding first flexible sub-layer 100, and receives a connection piece 430 for connecting a corresponding light-emitting element 300 to the corresponding light-emitting circuit 200. The connection piece 430 and part of the light-emitting element 300 may be made from the same material, or the connection piece 430 and a part of the light-emitting element 300 may be integrally formed. In the display panel 10a, the second flexible sub-layer 400 covers a part of the light-emitting circuit 200. In other words, the second flexible sub-layer 400 and the connection piece 430 cooperatively cover the light-emitting circuit 200 to prevent the light-emitting circuit 200 from being corroded by water vapor or oxygen.

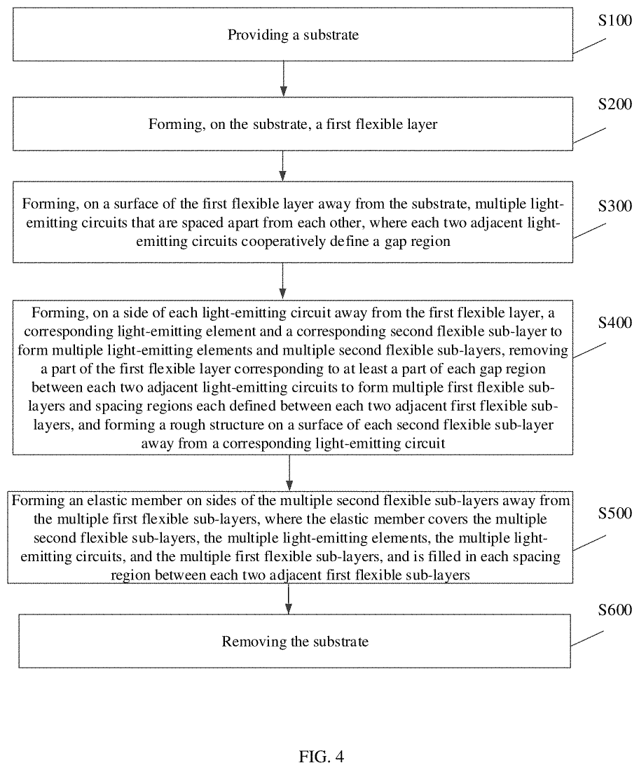

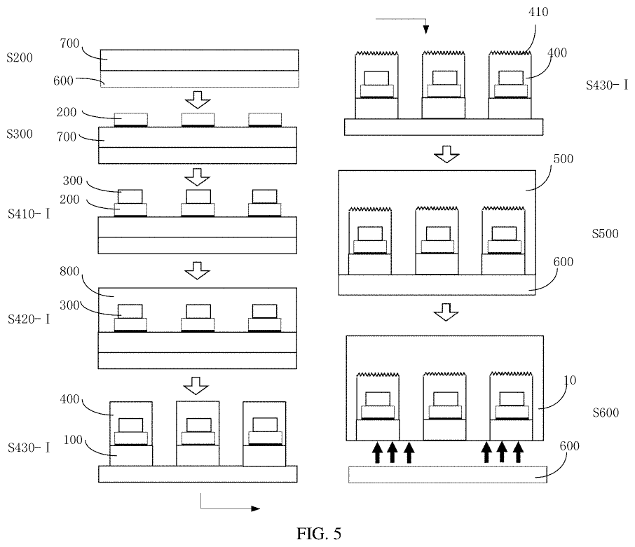

As illustrated in FIG. 1, FIG. 4, and FIG. 5, implementation of the disclosure further provide a manufacturing method of a display panel 10. The method begins at S100, and detailed steps are as follows.

At S100, a substrate 600 is provided. The substrate 600 is a rigid substrate and serves as a carrier for forming the display panel 10.

At S200, a first flexible layer 700 is formed on the substrate 600. The first flexible layer 700 is made from an organic layer, a metal sheet, or an ultra-thin glass that has a relatively good stretchability. The first flexible layer 700 may be formed by coating.

At S300, multiple light-emitting circuits 200 that are spaced apart from each other are respectively formed on a surface of the first flexible layer 700 away from the substrate 600, where there is a gap region 210 (as illustrated in FIG. 1) between each two adjacent light-emitting circuits 200. The light-emitting circuit 200 can be formed by adopting deposition and/or etching manners.

At S400, a corresponding light-emitting element 300 and a corresponding second flexible sub-layer 400 are formed on a side of each light-emitting circuit 200 away from the first flexible layer 700 to form multiple light-emitting elements 300 and multiple second flexible sub-layers 400, a part of the first flexible layer 700 corresponding to at least a part of each gap region 210 is removed to form multiple first flexible sub-layers 100 and spacing regions 110 each defined between each two adjacent first flexible sub-layers 100, and a rough structure 410 is formed on a surface of each second flexible sub-layer 400 away from a corresponding light-emitting circuit 200. As illustrated in FIG. 1, a width of the gap region 210 is larger than or equal to the spacing region 110. The rough structure 410 may be a microstructure, and the microstructure may have a cylindrical shape, a tapered shape, or an irregular shape. In at least one implementation, the rough structure 410 is formed on the surface of each second flexible sub-layer 400 away from the corresponding light-emitting circuit 200 as follows. Plasma etching is performed on the surface of each second flexible sub-layer 400 away from the corresponding light-emitting circuit 200 to form the rough structure 410.

At S500, an elastic member 500 is formed on sides of the multiple second flexible sub-layers 400 away from the multiple first flexible sub-layers 100, where the elastic member 500 covers the multiple second flexible sub-layers 400, the multiple light-emitting elements 300, the multiple light-emitting circuits 200, and the multiple first flexible sub-layers 100 and is filled in each spacing region 110.

At S600, the substrate 600 is removed. Since each second flexible sub-layer 400 is provided with the rough structure 410 on the surface in contact with the elastic member 500, the adhesion between the second flexible sub-layer 400 and the elastic member 500 is relatively high, when the substrate 600 is removed from the display panel 10, the elastic member 500 and the components inside the elastic member 500 are not separated. In other implementations, each second flexible sub-layer 400 can also be provided with the rough structures 410 on two side surfaces to further improve adhesion between the second flexible sub-layer 400 and the elastic member 500.

In the manufacturing method for the display panel 10 of the disclosure, each second flexible sub-layer 400 is provided with the rough structure 410 on the surface away from the light-emitting circuit 200, which can improve adhesion between the elastic member 500 and the second flexible sub-layers 400. In addition, since the light-emitting elements 300 in the display panel 10 of the disclosure are islanded with the first flexible sub-layers 100 that are spaced from each other, when the elastic member 500 is filled between the first flexible sub-layers 100, the flexibility of the display panel 10 can be further improved.

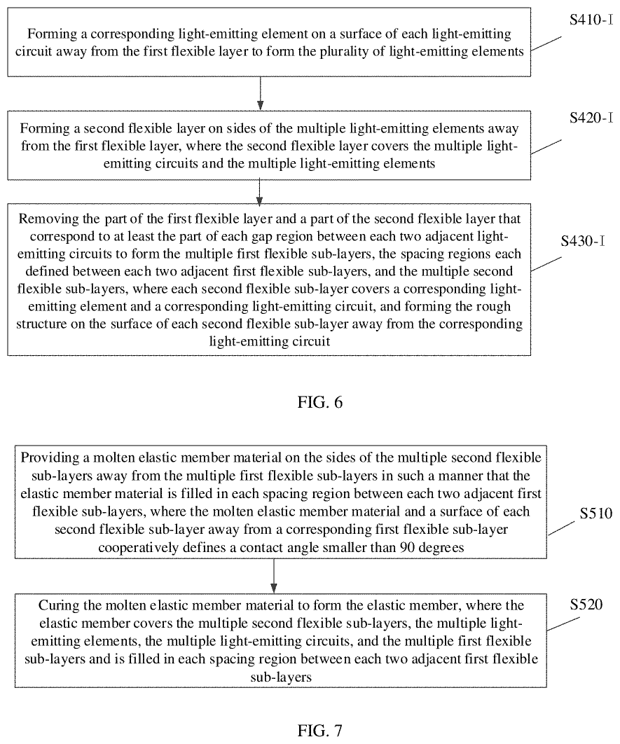

As illustrated in FIG. 6, in at least one implementation, the operations at S400 include operations at S410-I, S420-I, and S430-I. The details are as follows.

At S410-I, in combination with FIG. 5, a corresponding light-emitting element 300 is formed on a surface of each light-emitting circuit 200 away from the first flexible layer 700 to form the multiple light-emitting elements 300.

At S420-I, a second flexible layer 800 is formed on sides of the multiple light-emitting elements 300 away from the first flexible layer 700, where the second flexible layer 800 covers the multiple light-emitting circuits 200 and the multiple light-emitting elements 300. In one example, the second flexible layer 800 is made from a transparent organic material, such as transparent polyimide or acrylic.

At S430-I, the part of the first flexible layer 700 and a part of the second flexible layer 800 that correspond to at least the part of each gap region 210 between each two adjacent light-emitting circuits 100 are removed to form the multiple first flexible sub-layers 100, the spacing regions 110 each defined between each two adjacent first flexible sub-layers 100, and the multiple second flexible sub-layers 400, where each second flexible sub-layer 400 covers a corresponding light-emitting element 300 and a corresponding light-emitting circuit 200, and the rough structure 410 is formed on the surface of each second flexible sub-layer 400 away from the corresponding light-emitting circuit 200. In other words, the first flexible sub-layer 100 and the second flexible sub-layer 400 wrap the light-emitting circuit 200 and the light-emitting element 300 to prevent the light-emitting circuit 200 and the light-emitting element 300 from being corroded by water vapor or oxygen.

As illustrated in FIG. 7, in at least one implementation, operations at S500 include operations at S510 and S520. The details are as follows.

At S510, a molten elastic member material is provided on the sides of the multiple second flexible sub-layers 400 away from the multiple first flexible sub-layers 100 in such a manner that the elastic member material is filled in each spacing region 110 between each two adjacent first flexible sub-layers 100, where the molten elastic member material and a surface of each second flexible sub-layer 400 away from a corresponding first flexible sub-layer 100 cooperatively define a contact angle smaller than 90 degrees. For solid-liquid contact with the contact angle of smaller than 90 degrees, the rough surface facilitates surface wetting, thereby improving the adhesion between the elastic member 500 and the second flexible sub-layer 400. The materials of the elastic member 500 and the second flexible sub-layer 400 in the implementation of the disclosure are determined according to the contact angle (the contact angle smaller than 90 degrees is good) between the elastic member 500 in the molten state and the surface of the second flexible sub-layer 400 in contact with the elastic member 500.

At S520, the molten elastic member material is cured to form the elastic member 500, where the elastic member 500 covers the multiple second flexible sub-layers 400, the multiple light-emitting elements 300, the multiple light-emitting circuits 200, and the multiple first flexible sub-layers 100 and is filled in each spacing region 110 between each two adjacent first flexible sub-layers 100.

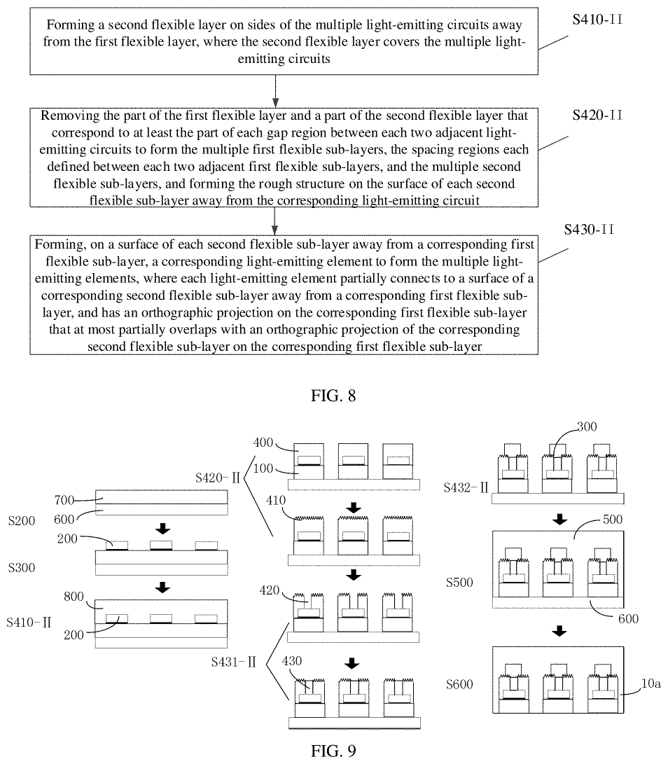

As illustrated in FIG. 2, FIG. 8, and FIG. 9, implementations of the disclosure further provide a manufacturing method of a display panel 10a. Different from the manufacturing method of a display panel 10, operations at S400 in the manufacturing method of a display panel 10a include operations at S410-II, S420-II, and S430-II.

At S410-II, a second flexible layer 800 is formed on sides of the multiple light-emitting circuits 200 away from the first flexible layer 700, where the second flexible layer 800 covers the multiple light-emitting circuits 200.

At S420-II, the part of the first flexible layer 700 and a part of the second flexible layer 800 that correspond to at least the part of each gap region 210 between each two adjacent light-emitting circuits 200 are removed to form the multiple first flexible sub-layers 100, the spacing regions 110 each defined between each two adjacent first flexible sub-layers 100, and the multiple second flexible sub-layers 400, and the rough structure 410 is formed on the surface of each second flexible sub-layer 400 away from the corresponding light-emitting circuit 200.

At S430-II, a corresponding light-emitting element 300 is formed on a surface of each second flexible sub-layer 400 away from a corresponding first flexible sub-layer 100 to form the multiple light-emitting elements 300, where each light-emitting element 300 partially connects to a surface of a corresponding second flexible sub-layer 400 away from a corresponding first flexible sub-layer 100, and has an orthographic projection on the corresponding first flexible sub-layer 100 that at most partially overlaps with an orthographic projection of the corresponding second flexible sub-layer 400 on the corresponding first flexible sub-layer 100.

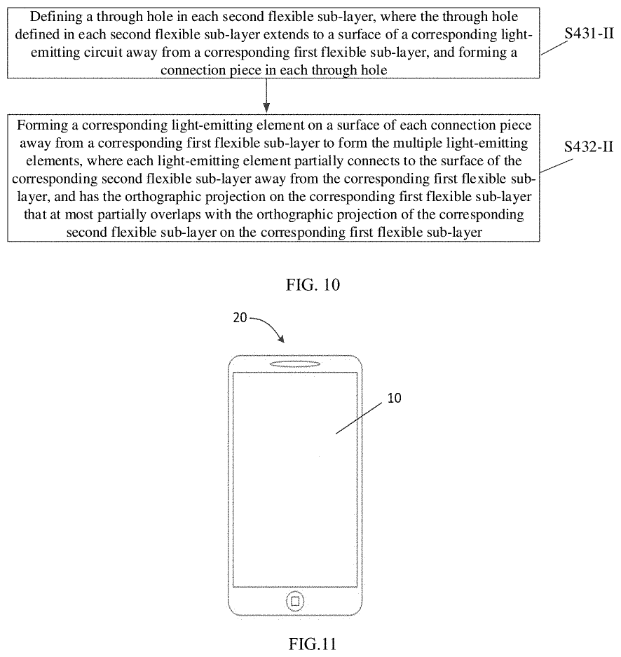

As illustrated in FIG. 10, in at least one implementation, operations at S430-II include operations at S431-II and S432-II.

At S431-II, a through hole 420 is defined in each second flexible sub-layer 400, where the through hole 420 defined in each second flexible sub-layer 400 extends to a surface of a corresponding light-emitting circuit 200 away from a corresponding first flexible sub-layer 100, and a connection piece 430 is formed in each through hole 420. The through hole 420 can be defined in the second flexible sub-layer 400 by an etching process.

At S432-II, a corresponding light-emitting element 300 is formed on a surface of each connection piece 430 away from a corresponding first flexible sub-layer 100 to form the multiple light-emitting elements 300, where each light-emitting element 300 partially connects to the surface of the corresponding second flexible sub-layer 400 away from the corresponding first flexible sub-layer 100, and has the orthographic projection on the corresponding first flexible sub-layer 100 that at most partially overlaps with the orthographic projection of the corresponding second flexible sub-layer 400 on the corresponding first flexible sub-layer 100.

As illustrated in FIG. 11, implementations of the disclosure further provide an electronic device 20. The electronic device 20 includes the display panel 10 described in any implementation of the disclosure. The electronic device 30 may be, but is not limited to, an e-book, a smart phone (such as an Android® phone, an iOS® phone, a Windows® phone, etc.), a tablet computer, a flexible handheld computer, a flexible notebook computer, a mobile internet device (MID), or a wearable device, etc., or may be an organic light-emitting diodes (OLED) electronic device, or an active matrix organic light emitting diode (AMOLED) electronic device.

The foregoing merely describes some implementations of the disclosure, and their description is relatively specific and detailed, but they should not be understood as a limitation to the patent scope of the disclosure. It should be noted that for those of ordinary skill in the art, various modifications and improvements can be made without departing from the concept of the disclosure, which all fall within the protection scope of the disclosure. Therefore, the protection scope of the disclosure should be subject to the appended claims.

What is claimed is:

1. A display panel, comprising:
a plurality of first flexible sub-layers, wherein the plurality of first flexible sub-layers are spaced apart from each other, and each two adjacent first flexible sub-layers cooperatively define a spacing region;
a plurality of light-emitting circuits, wherein each light-emitting circuit is arranged on a side of a corresponding first flexible sub-layer;
a plurality of light-emitting elements, wherein for each light-emitting element, the light-emitting element is arranged on a side of a corresponding light-emitting circuit away from a corresponding first flexible sub-layer, and is coupled to the corresponding light-emitting circuit, and different light-emitting elements are electrically coupled to different light-emitting circuits;
a plurality of second flexible sub-layers, wherein for each second flexible sub-layer, the second flexible sub-layer is in contact with a surface of a corresponding light-emitting circuit away from a corresponding first flexible sub-layer, at least partially covers the corresponding light-emitting circuit, and is provided with a rough structure on a surface away from the corresponding first flexible sub-layer; and
an elastic member, wherein the elastic member is arranged on sides of the plurality of second flexible sub-layers away from the plurality of first flexible sub-layers, and covers the plurality of second flexible sub-layers, the plurality of light-emitting elements, the plurality of light-emitting circuits, and the plurality of first flexible sub-layers, and is filled in each spacing region between each two adjacent first flexible sub-layers.

2. The display panel of claim 1, wherein each light-emitting circuit comprises a driving circuit consisted of thin film transistors, wherein the light-emitting circuits on each two adjacent first flexible sub-layers are coupled via a connection line to form a driving circuit array.

3. The display panel of claim 1, wherein the first flexible sub-layer and the second flexible sub-layer each comprise an organic layer, a metal sheet, or an ultra-thin glass.

4. The display panel of claim 1, wherein for each second flexible sub-layer, the second flexible sub-layer is in contact with a surface of a corresponding light-emitting element away from a corresponding first flexible sub-layer, and covers a corresponding light-emitting circuit and the corresponding light-emitting element.

5. The display panel of claim 1, wherein for each light-emitting element, the light-emitting element is arranged on a surface of a corresponding second flexible sub-layer away from a corresponding first flexible sub-layer, and has an orthographic projection on the corresponding first flexible sub-layer that at most partially overlaps with an orthographic projection of the corresponding second flexible sub-layer on the corresponding first flexible sub-layer.

6. The display panel of claim 5, wherein each second flexible sub-layer defines a through hole, wherein the through hole defined in each second flexible sub-layer extends to a surface of a corresponding light-emitting circuit away from a corresponding first flexible sub-layer, and receives a connection piece for connecting a corresponding light-emitting element to the corresponding light-emitting circuit.

7. The display panel of claim 1, wherein the elastic member in a molten state and a surface of the second flexible sub-layer in contact with the elastic member cooperatively define a contact angle smaller than 90 degrees.

8. The display panel of claim 1, wherein the rough structure is a microstructure, wherein the microstructure has a cylindrical shape, a tapered shape, or an irregular shape.

9. The display panel of claim 1, wherein the light-emitting element is an inorganic light-emitting diode or an organic light-emitting diode.

10. The display panel of claim 1, wherein the first flexible sub-layer and the second flexible sub-layer are both made from polyimide or acrylic acid.

11. A manufacturing method of a display panel, comprising:
providing a substrate;
forming, on the substrate, a first flexible layer;
forming, on a surface of the first flexible layer away from the substrate, a plurality of light-emitting circuits that are spaced apart from each other, wherein each two adjacent light-emitting circuits cooperatively define a gap region;
forming, on a side of each light-emitting circuit away from the first flexible layer, a corresponding light-emitting element and a corresponding second flexible sub-layer to form a plurality of light-emitting elements and a plurality of second flexible sub-layers, removing a part of the first flexible layer corresponding to at least a part of each gap region between each two adjacent light-emitting circuits to form a plurality of first flexible sub-layers and spacing regions each defined between each two adjacent first flexible sub-layers, and forming a rough structure on a surface of each second flexible sub-layer away from a corresponding light-emitting circuit;
forming an elastic member on sides of the plurality of second flexible sub-layers away from the plurality of first flexible sub-layers, wherein the elastic member covers the plurality of second flexible sub-layers, the plurality of light-emitting elements, the plurality of light-emitting circuits, and the plurality of first flexible sub-layers, and is filled in each spacing region between each two adjacent first flexible sub-layers; and
removing the substrate.

12. The manufacturing method of claim 11, wherein “forming, on the side of each light-emitting circuit away from the first flexible layer, the corresponding light-emitting element and the corresponding second flexible sub-layer to form the plurality of light-emitting elements and the plurality of second flexible sub-layers, removing the part of the first flexible layer corresponding to at least the part of each gap region between each two adjacent light-emitting circuits to form the plurality of first flexible sub-layers and the spacing regions each defined between each two adjacent first flexible sub-layers, and forming the rough structure on the surface of each second flexible sub-layer away from the corresponding light-emitting circuit” comprises:
forming a corresponding light-emitting element on a surface of each light-emitting circuit away from the first flexible layer to form the plurality of light-emitting elements;
forming a second flexible layer on sides of the plurality of light-emitting elements away from the first flexible layer, wherein the second flexible layer covers the plurality of light-emitting circuits and the plurality of light-emitting elements;
removing the part of the first flexible layer and a part of the second flexible layer that correspond to at least the part of each gap region between each two adjacent light-emitting circuits to form the plurality of first flexible sub-layers, the spacing regions each defined between each two adjacent first flexible sub-layers, and the plurality of second flexible sub-layers, wherein each second flexible sub-layer covers a corresponding light-emitting element and a corresponding light-emitting circuit; and
forming the rough structure on the surface of each second flexible sub-layer away from the corresponding light-emitting circuit.

13. The manufacturing method of claim 11, wherein “forming, on the side of each light-emitting circuit away from the first flexible layer, the light-emitting element and the second flexible sub-layer to form the plurality of light-emitting elements and the plurality of second flexible sub-layers, removing the part of the first flexible layer corresponding to at least the part of each gap region between each two adjacent light-emitting circuits to form the plurality of first flexible sub-layers and the spacing regions each defined between each two adjacent first flexible sub-layers, and forming the rough structure on the surface of each second flexible sub-layer away from the corresponding light-emitting circuit” comprises:
forming a second flexible layer on sides of the plurality of light-emitting circuits away from the first flexible layer, wherein the second flexible layer covers the plurality of light-emitting circuits;
removing the part of the first flexible layer and a part of the second flexible layer that correspond to at least the part of each gap region between each two adjacent light-emitting circuits to form the plurality of first flexible sub-layers, the spacing regions each defined between each two adjacent first flexible sub-layers, and the plurality of second flexible sub-layers, and forming the rough structure on the surface of each second flexible sub-layer away from the corresponding light-emitting circuit; and
forming, on a surface of each second flexible sub-layer away from a corresponding first flexible sub-layer, a corresponding light-emitting element to form the plurality of light-emitting elements, wherein each light-emitting element partially connects to a surface of a corresponding second flexible sub-layer away from a corresponding first flexible sub-layer, and has an orthographic projection on the corresponding first flexible sub-layer that at most partially overlaps with an orthographic projection of the corresponding second flexible sub-layer on the corresponding first flexible sub-layer.

14. The manufacturing method of claim 13, wherein “forming, on the surface of each second flexible sub-layer away from the corresponding first flexible sub-layer, the corresponding light-emitting element to form the plurality of light-emitting elements, wherein each light-emitting element partially connects to the surface of the corresponding second flexible sub-layer away from the corresponding first flexible sub-layer are partially coupled, and has the orthographic projection on the corresponding first flexible sub-layer that at most partially overlaps with the orthographic projection of the corresponding second flexible sub-layer on the corresponding first flexible sub-layer” comprises:
defining a through hole in each second flexible sub-layer, wherein the through hole defined in each second flexible sub-layer extends to a surface of a corresponding light-emitting circuit away from a corresponding first flexible sub-layer, and forming a connection piece in each through hole; and
forming a corresponding light-emitting element on a surface of each connection piece away from a corresponding first flexible sub-layer to form the plurality of light-emitting elements, wherein each light-emitting element partially connects to the surface of the corresponding second flexible sub-layer away from the corresponding first flexible sub-layer, and has the orthographic projection on the corresponding first flexible sub-layer that at most partially overlaps with the orthographic projection of the corresponding second flexible sub-layer on the corresponding first flexible sub-layer.

15. The manufacturing method of claim 11, wherein forming the elastic member on the sides of the plurality of second flexible sub-layers away from the plurality of first flexible sub-layers comprises:
providing a molten elastic member material on the sides of the plurality of second flexible sub-layers away from the plurality of first flexible sub-layers in such a manner that the elastic member material is filled in each spacing region between each two adjacent first flexible sub-layers, wherein the molten elastic member material and a surface of each second flexible sub-layer away from a corresponding first flexible sub-layer cooperatively define a contact angle smaller than 90 degrees; and
curing the molten elastic member material to form the elastic member, wherein the elastic member covers the plurality of second flexible sub-layers, the plurality of light-emitting elements, the plurality of light-emitting circuits, and the plurality of first flexible sub-layers and is filled in each spacing region between each two adjacent first flexible sub-layers.

16. The manufacturing method of claim 11, wherein the rough structure is a microstructure, wherein the microstructure has a cylindrical shape, a tapered shape, or an irregular shape.

17. The manufacturing method of claim 11, wherein forming the rough structure on the surface of each second flexible sub-layer away from the corresponding light-emitting circuit comprises:
performing plasma etching on the surface of each second flexible sub-layer away from the corresponding light-emitting circuit to form the rough structure.

18. An electronic device comprising:
a plurality of first flexible sub-layers, wherein the plurality of first flexible sub-layers are spaced apart from each other, and each two adjacent first flexible sub-layers cooperatively define a spacing region;
a plurality of light-emitting circuits, wherein each light-emitting circuit is arranged on a side of a corresponding first flexible sub-layer;
a plurality of light-emitting elements, wherein for each light-emitting element, the light-emitting element is arranged on a side of a corresponding light-emitting circuit away from a corresponding first flexible sub-layer, and is coupled to the corresponding light-emitting circuit, and different light-emitting elements are electrically coupled to different light-emitting circuits;
a plurality of second flexible sub-layers, wherein for each second flexible sub-layer, the second flexible sub-layer is in contact with a surface of a corresponding light-emitting circuit away from a corresponding first flexible sub-layer, at least partially covers the corresponding light-emitting circuit, and is provided with a rough structure on a surface away from the corresponding first flexible sub-layer; and
an elastic member, wherein the elastic member is arranged on sides of the plurality of second flexible sub-layers away from the plurality of first flexible sub-layers, and covers the plurality of second flexible sub-layers, the plurality of light-emitting elements, the plurality of light-emitting circuits, and the plurality of first flexible sub-layers, and is filled in each spacing region between each two adjacent first flexible sub-layers.

19. The electronic device of claim 18, wherein for each second flexible sub-layer, the second flexible sub-layer is in contact with a surface of a corresponding light-emitting element away from a corresponding first flexible sub-layer, and covers a corresponding light-emitting circuit and the corresponding light-emitting element.

20. The electronic device of claim 18, wherein for each light-emitting element, the light-emitting element is arranged on a surface of a corresponding second flexible sub-layer away from a corresponding first flexible sub-layer, and has an orthographic projection on the corresponding first flexible sub-layer that at most partially overlaps with an orthographic projection of the corresponding second flexible sub-layer on the corresponding first flexible sub-layer.
